(19) United States
(12) Patent Application Publication
(10) Pub. No.: US 2026/0110929 A1
(43) Pub. Date: Apr. 23, 2026

(54) DIELECTRIC THIN FILM DEPOSITED SUBSTRATE, DIELECTRIC THIN FILM DEPOSITED SUBSTRATE MANUFACTURING METHOD, OPTICAL WAVEGUIDE ELEMENT, AND OPTICAL MODULATION ELEMENT

(71) Applicant: TDK CORPORATION, Tokyo (JP)

(72) Inventors: Kenji SASAKI, Tokyo (JP); Takashi KIKUKAWA, Tokyo (JP); Katsumi KAWASAKI, Tokyo (JP)

(73) Assignee: TDK CORPORATION, Tokyo (JP)

(21) Appl. No.: 19/359,390

(22) Filed: Oct. 15, 2025

(30) Foreign Application Priority Data
Oct. 21, 2024 (JP) 2024-184927

(51) Int. Cl. G02F 1/055; C23C 14/06; C23C 14/34; G02F 1/03; G02F 1/035; G02F 1/355

(52) U.S. Cl. CPC G02F 1/0553; C23C 14/06; C23C 14/34; G02F 1/0316; G02F 1/035; G02F 1/3551; G02F 2201/07; G02F 2202/20

(57) ABSTRACT

Provided is a dielectric thin film deposited substrate which includes a single crystal substrate having a c-axis aligned in an in-plane direction and a dielectric thin film formed on and in contact with the single crystal substrate and in which the dielectric thin film is made of a lithium niobate film having a c-axis oriented in one in-plane direction. In the dielectric thin film deposited substrate, an angle formed between the c-axis direction of the single crystal substrate and the c-axis direction of the lithium niobate film is preferably 0.4° to 5°.

### CROSS-REFERENCES TO RELATED APPLICATIONS

This application relies for priority upon Japanese Patent Application No. 2024-184927 filed on Oct. 21, 2024, the entire content of which is hereby incorporated herein by reference for all purposes as if fully set forth herein.

### BACKGROUND

The present disclosure relates to a dielectric thin film deposited substrate, a dielectric thin film deposited substrate manufacturing method, an optical waveguide element, and an optical modulation element.

Conventionally, there is an optical modulation element that uses a lithium niobate film epitaxially grown on a substrate.

For example, Patent Document 1 describes an optical modulation element using a dielectric thin film deposited substrate. That is, Patent Document 1 describes a dielectric thin film deposited substrate which includes a single crystal substrate and a dielectric thin film made of c-axis oriented lithium niobate epitaxially formed on a main surface of the single crystal substrate.

Further, Patent Document 2 describes a laminated structure which includes a single crystal substrate, a dielectric layer made of lithium niobate, and a buffer layer disposed between the single crystal substrate and the dielectric layer. That is, Patent Document 2 describes that the c-axis of the crystal constituting the dielectric layer of the laminated structure is approximately parallel to the main surface of the single crystal substrate and the c-axis of the crystal constituting the buffer layer is approximately parallel to the main surface of the single crystal substrate.

### PATENT DOCUMENTS

[Patent Document 1] PCT International Publication No. WO 2018/016428
[Patent Document 2] Japanese Unexamined Patent Application, First Publication No. 2016-109856

### SUMMARY

The light propagating through the optical waveguide of the optical modulation element exists in two modes: TE (Transverse Electric) mode and TM (Transverse Magnetic) mode. In the TE mode, the polarization direction of the light is the in-plane direction of the substrate of the optical modulation element. In the TM mode, the polarization direction of the light is perpendicular to the in-plane direction of the substrate of the light modulation element. The TE mode and the TM mode have different optical characteristics such as the effective refractive index and modulation efficiency of light incident on the optical waveguide of the optical modulation element.

In an optical modulation element having an optical waveguide made of a lithium niobate film, the electro-optic coefficient becomes largest when the polarization direction of light incident on the optical waveguide matches the c-axis of the lithium niobate film.

Therefore, for example, when the c-axis of the optical waveguide made of the lithium niobate film of the optical modulation element is parallel to the thickness direction of the substrate, if TE mode light emitted from a laser light source is incident, the polarization direction of the light differs from the c-axis direction of the lithium niobate film, and therefore the voltage required for modulation increases.

One method of solving this problem is to convert the TE mode light emitted from the laser light source into TM mode light using an optical conversion device and then allow the light to be incident on an optical waveguide made of a lithium niobate film in the optical modulation element. By using this method, when the c-axis of the optical waveguide made of a lithium niobate film is parallel to the thickness direction of the substrate, the polarization direction of light incident on the optical waveguide can be made to match the c-axis of the lithium niobate film. However, when such a method is used, optical loss caused by converting TE mode light into TM mode light cannot be avoided.

On the other hand, when the optical waveguide of the optical modulation element is made of a lithium niobate film having a c-axis parallel to the in-plane direction of the substrate, it is not necessary to convert the TE mode light emitted from the laser light source into TM mode light before the light is incident on the optical waveguide. Therefore, no optical loss occurs due to conversion of TE mode light to TM mode light unlike the case where a lithium niobate film having a c-axis parallel to the thickness direction of the substrate is used.

However, when the buffer layer is provided between the single crystal substrate and the dielectric layer as in the laminated structure described in Patent Document 2, problems such as leakage of propagating light arise when the dielectric layer is used as the optical waveguide of the optical modulation element.

The present disclosure has been made in view of the above-described circumstances and an object of the present disclosure is to provide a dielectric thin film deposited substrate that has a dielectric thin film made of a lithium niobate film and can form an optical waveguide of an optical modulation element having a low driving voltage and low optical loss, and a method of manufacturing the same.

Further, an object of the present disclosure is to provide an optical waveguide element that can be used as an optical waveguide of an optical modulation element having a low driving voltage and low optical loss and provided with a dielectric thin film deposited substrate having a dielectric thin film made of a lithium niobate film.

Further, an object of the present disclosure is to provide an optical modulation element having a low driving voltage and low optical loss and provided with a dielectric thin film deposited substrate having a dielectric thin film made of a lithium niobate film.

A dielectric thin film deposited substrate according to an aspect of the present disclosure includes: a single crystal substrate having a c-axis oriented in an in-plane direction; and a dielectric thin film formed on and in contact with the single crystal substrate, wherein the dielectric thin film is made of a lithium niobate film having a c-axis aligned in one in-plane direction.

The dielectric thin film deposited substrate of the present disclosure includes: the single crystal substrate having a c-axis oriented in the in-plane direction; and the dielectric thin film formed on and in contact with the single crystal substrate, wherein the dielectric thin film is made of a lithium niobate film having a c-axis aligned in one in-plane direction. Therefore, for example, by forming an optical waveguide into which TE mode light is incident using the dielectric thin film of the dielectric thin film deposited substrate of the present disclosure, it is possible to form an optical waveguide of an optical modulation element which has low driving voltage and low optical loss and in which the polarization direction of the light incident on the optical waveguide matches the c-axis of the lithium niobate film.

For this reason, the dielectric thin film deposited substrate of the present disclosure can be preferably used as a material for optical waveguide elements and optical modulation elements.

Further, the optical waveguide element of the present disclosure includes: the dielectric thin film deposited substrate of the present disclosure; and an optical waveguide made of a lithium niobate film having a c-axis aligned in one in-plane direction. Therefore, the optical waveguide element of the present disclosure can be suitably used as an optical waveguide of an optical modulation element which has a low driving voltage and low optical loss and in which the polarization direction of the light incident on the optical waveguide matches the c-axis of the lithium niobate film, for example, when TE mode light is incident on the optical waveguide.

Further, the optical modulation element of the present disclosure includes: the dielectric thin film deposited substrate of the present disclosure; an optical waveguide made of a lithium niobate film having a c-axis aligned in one in-plane direction; and a first electrode and a second electrode provided on a dielectric thin film made of a lithium niobate film and arranged opposite to each other and spaced apart in the in-plane direction, wherein the optical waveguide is disposed between the first electrode and the second electrode. Therefore, in the optical modulation element of the present disclosure, the driving voltage and optical loss are low and the polarization direction of the light incident on the optical waveguide matches the c-axis of the lithium niobate film when TE mode light is incident on the optical waveguide.

Further, in the optical waveguide element and the optical modulation element of the present disclosure, the c-axis direction of the lithium niobate film forming the optical waveguide matches the polarization direction of the TE mode light. Therefore, in the optical waveguide element and the optical modulation element of the present disclosure, there is no need to convert the polarization direction of light using an optical conversion device before the light is incident on the optical waveguide, and no optical loss occurs due to the conversion of the polarization direction of light.

A dielectric thin film deposited substrate manufacturing method of the present disclosure includes: a dielectric thin film forming step of growing a lithium niobate film having a c-axis aligned in one in-plane direction on a single crystal substrate having a c-axis oriented in the in-plane direction by a vapor deposition method. Therefore, according to the dielectric thin film deposited substrate manufacturing method of the present disclosure, the dielectric thin film deposited substrate of the present disclosure can be easily manufactured.

### BRIEF DESCRIPTION OF THE DRAWINGS

FIG. 1A is a schematic cross-sectional view showing a dielectric thin film deposited substrate according to an embodiment of the present disclosure.

FIG. 1B is a plan view showing a single crystal substrate forming the dielectric thin film deposited substrate shown in FIG. 1A.

FIG. 1C is a plan view showing a dielectric thin film forming the dielectric thin film deposited substrate shown in FIG. 1A.

FIG. 2A is a diagram illustrating the arrangement of Al atoms in a sapphire single crystal substrate, and is a schematic view showing the arrangement as viewed from the c-axis direction.

FIG. 2B is a diagram illustrating the arrangement of Al atoms in a sapphire single crystal substrate, and is a schematic view showing the arrangement on an a-plane (1100).

FIG. 2C is a diagram illustrating the arrangement of Nb atoms and Li atoms in a lithium niobate film, and is a schematic view showing the arrangement as viewed from the c-axis direction.

FIG. 2D is a diagram illustrating the arrangement of Nb atoms and Li atoms in a lithium niobate film, and is a schematic view showing the arrangement on an a-plane (1100).

FIG. 3 is a plan view showing an example of an optical waveguide element 100 provided with a dielectric thin film deposited substrate 1 shown in FIG. 1.

FIG. 4 is a cross-sectional view of the optical waveguide element 100 shown in FIG. 3 taken along the line A-A′.

FIG. 5 is a plan view showing an example of a Mach-Zehnder type optical modulation element 200 provided with the dielectric thin film deposited substrate 1 shown in FIG. 1.

FIG. 6 is a cross-sectional view of the optical modulation element 200 shown in FIG. 5 taken along the line B-B′.

FIG. 7 is a profile of X-ray diffraction intensity obtained by the measurement (φ scan) of an in-plane X-ray diffraction intensity of a lithium niobate film forming a dielectric thin film 3 of a dielectric thin film deposited substrate of Example 1.

FIG. 8 is a diagram showing the results of measuring the X-ray diffraction poles of the lithium niobate film forming the dielectric thin film 3 of the dielectric thin film deposited substrate of Example 1.

FIG. 9 shows X-ray diffraction intensity profiles obtained by the measurement (φ scan) of in-plane X-ray diffraction intensities of a sapphire single crystal substrate forming a single crystal substrate 2 of the dielectric thin film deposited substrate of Example 1 and a lithium niobate film forming the dielectric thin film 3.

FIG. 10A is an X-ray diffraction intensity profile shown by enlarging a part of FIG. 9 and is a profile near an angle of 85° on the φ axis.

FIG. 10B is an X-ray diffraction intensity profile shown by enlarging a part of FIG. 9 and is a profile near an angle of 265° on the φ axis.

### DETAILED DESCRIPTION

The present inventors have focused on the c-axis direction of the lithium niobate film and conducted extensive research as described below in order to solve the above-described problems and to obtain a dielectric thin film deposited substrate having a dielectric thin film that can form an optical modulation element with a low driving voltage and low optical loss when used as a material for the optical modulation element having an optical waveguide made of a lithium niobate film into which TE mode light emitted from a laser light source or the like is incident.

That is, the present inventors considered that it would be sufficient to use an optical waveguide made of a lithium niobate film having a c-axis aligned in one in-plane direction of a substrate in order to match the polarization direction of light and the c-axis direction of the lithium niobate film when TE mode light is incident on an optical waveguide made of a lithium niobate film included in an optical modulation element.

However, in the conventional techniques, it has not been possible to grow a lithium niobate film on a single crystal substrate and having a c-axis aligned in one in-plane direction of the substrate.

As a method of solving this problem, it is considered to use a method of attaching a lithium niobate film having a c-axis aligned in one in-plane direction of the substrate to the substrate. However, the method of attaching a dielectric thin film onto a substrate is not preferable because it is less productive and more costly.

Therefore, the present inventors have conducted extensive research into a method of growing a lithium niobate film on a substrate in contact with the substrate having a c-axis aligned in one in-plane direction of the substrate.

As a result, the present inventors discovered that a lithium niobate film having a c-axis aligned in one in-plane direction of a substrate can be formed by growing a lithium niobate film by a vapor deposition method on a single crystal substrate having a c-axis oriented in the in-plane direction, and thus arrived at the present disclosure.

The present disclosure includes the following aspects.

[1] A dielectric thin film deposited substrate including:
a single crystal substrate having a c-axis oriented in an in-plane direction; and
a dielectric thin film formed on and in contact with the single crystal substrate,
wherein the dielectric thin film is made of a lithium niobate film having a c-axis aligned in one in-plane direction.

[2] The dielectric thin film deposited substrate according to [1],
wherein an angle formed between the c-axis direction of the single crystal substrate and the c-axis direction of the lithium niobate film is 0.4° to 5°.

[3] The dielectric thin film deposited substrate according to [1],
wherein the single crystal substrate is a sapphire single crystal substrate.

[4] The dielectric thin film deposited substrate according to [1],
wherein the lithium niobate film is grown by a vapor deposition method.

[5] The dielectric thin film deposited substrate according to [1],
wherein the lithium niobate film is grown by sputtering.

[6] An optical waveguide element including:
the dielectric thin film deposited substrate according to any one of [1] to [5]; and
an optical waveguide made of the dielectric thin film.

[7] An optical modulation element including:
the dielectric thin film deposited substrate according to any one of [1] to [5];
an optical waveguide made of the dielectric thin film; and
a first electrode and a second electrode provided on the dielectric thin film and arranged opposite to each other and spaced apart in the in-plane direction,
wherein the optical waveguide is disposed between the first electrode and the second electrode.

[8] A method of manufacturing the dielectric thin film deposited substrate according to any one of [1] to [5], including:
a dielectric thin film forming step of growing, by a vapor deposition method, a lithium niobate film having a c-axis aligned in one in-plane direction on a single crystal substrate having a c-axis oriented in the in-plane direction.

[9] The dielectric thin film deposited substrate manufacturing method according to [8],
wherein the vapor deposition method is sputtering.

Hereinafter, a dielectric thin film deposited substrate, a dielectric thin film deposited substrate manufacturing method, an optical waveguide element, and an optical modulation element of this embodiment will be described in detail with appropriate reference to the drawings. The drawings used in the following description may show characteristic parts enlarged for the sake of convenience in order to make the features of the present disclosure easier to understand. Therefore, the dimensional proportions of each component may differ from the actual ones. The materials, dimensions, etc. exemplified in the following description are merely examples, and the present disclosure is not limited to them. The present disclosure can be implemented by making appropriate changes within the scope that does not change the gist of the present disclosure.

### [Dielectric Thin Film Deposited Substrate]

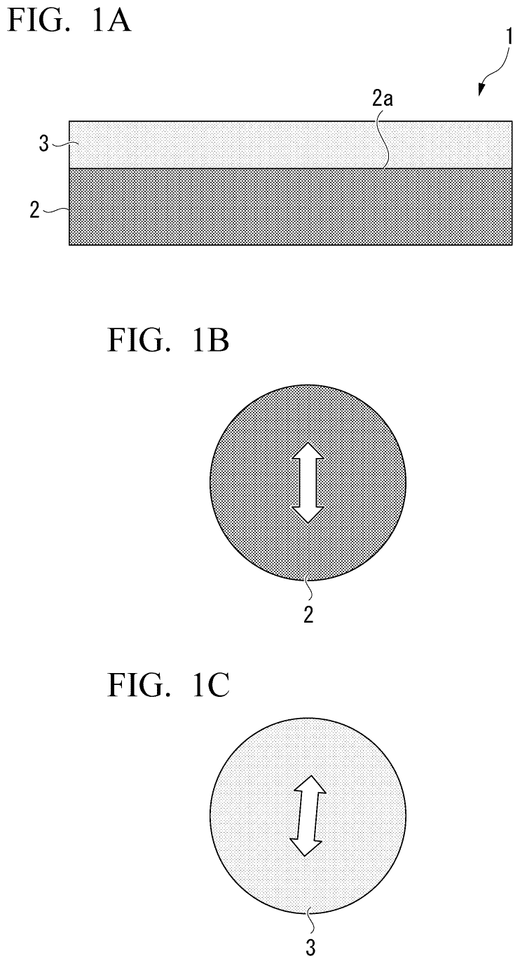

FIG. 1A is a schematic cross-sectional view showing a dielectric thin film deposited substrate according to an embodiment of the present disclosure. FIG. 1B is a plan view showing a single crystal substrate that forms the dielectric thin film deposited substrate shown in FIG. 1A. FIG. 1C is a plan view showing a dielectric thin film that forms the dielectric thin film deposited substrate shown in FIG. 1A. As shown in FIGS. 1A to 1C, a dielectric thin film deposited substrate 1 according to this embodiment has a single crystal substrate 2 having a substantially circular shape in plan view and a dielectric thin film 3 formed on and in contact with a main surface 2a of the single crystal substrate 2.

### (Single Crystal Substrate 2)

The single crystal substrate 2 forming the dielectric thin film deposited substrate 1 of this embodiment has a c-axis oriented in the in-plane direction, and the crystal orientation of the main surface 2a is the a-plane. The arrow shown in FIG. 1B indicates the c-axis direction of the single crystal substrate 2. The single crystal substrate 2 may be a single crystal substrate having a c-axis oriented in the in-plane direction, and any known single crystal substrate may be used. The single crystal substrate 2 preferably has a refractive index lower than that of lithium niobate, and for example, a sapphire single crystal substrate, a silicon single crystal substrate, or the like can be used.

In the dielectric thin film deposited substrate 1 of this embodiment, it is particularly preferable to use a sapphire single crystal substrate as the single crystal substrate 2. The sapphire single crystal substrate has a lower refractive index than lithium niobate (LiNbO₃). Therefore, for example, when the dielectric thin film 3 of the dielectric thin film deposited substrate 1 is used as an optical waveguide layer of an optical waveguide element and/or an optical modulation element, this film can serve as a cladding layer. Therefore, when the single crystal substrate 2 is a sapphire single crystal substrate, the dielectric thin film 3 can be suitably used as an optical waveguide layer of an optical waveguide element and/or an optical modulation element without providing an additional layer between the single crystal substrate 2 and the dielectric thin film 3.

### (Dielectric Thin Film 3)

The dielectric thin film 3 forming the dielectric thin film deposited substrate 1 of this embodiment is made of a lithium niobate film. The c-axis of the lithium niobate film is aligned in one in-plane direction of the single crystal substrate 2. The arrow shown in FIG. 1C indicates the c-axis direction of the lithium niobate film forming the dielectric thin film 3.

The composition of the lithium niobate film forming the dielectric thin film 3 is expressed by the general formula LixNbAyOz (wherein A is an element other than Li, Nb, and O, x is 0.5 to 1.2, y is 0 to 0.5, and z is 1.5 to 4).

In the formula, A represents an element other than Li, Nb, and O. Examples of elements represented by A include K, Na, Rb, Cs, Be, Mg, Ca, Sr, Ba, Ti, Zr, Hf, V, Cr, Mo, W, Fe, Co, Ni, Zn, Sc, Ce, and Ta. The element represented by A may be of only one type or of two or more types.

In the formula, x is 0.5 to 1.2, preferably 0.9 to 1.05.

In the formula, y is 0 to 0.5.

In the formula, z is 1.5 to 4, preferably 2.5 to 3.5.

The lithium niobate film forming the dielectric thin film 3 is a film mainly consisting of lithium niobate (LiNbO₃). Lithium niobate has a large electro-optic constant and is therefore suitable as a material for the optical waveguide layer of optical waveguide elements and optical modulation elements. The lithium niobate film forming the dielectric thin film 3 is preferably a single phase consisting of LiNbO₃.

The thickness of the dielectric thin film 3 can be set to, for example, 0.5 μm to 2 μm. If the thickness of the dielectric thin film 3 is 0.5 μm or more, it is preferable in that the dielectric thin film 3 is applicable to a wide range of light from visible light to infrared light when the dielectric thin film 3 of the dielectric thin film deposited substrate 1 is used as an optical waveguide layer of an optical modulation element. Further, if the thickness of the dielectric thin film 3 is 2 μm or less, when the dielectric thin film 3 of the dielectric thin film deposited substrate 1 is processed into a ridge shape, the occurrence of cracks in the lithium niobate film forming the dielectric thin film 3 can be effectively suppressed.

The lithium niobate film forming the dielectric thin film 3 is preferably grown on the single crystal substrate 2 by a vapor deposition method. In the lithium niobate film grown by a vapor deposition method and in contact with the single crystal substrate 2 having a c-axis oriented in the in-plane direction, the angle formed between the c-axis direction of the single crystal substrate 2 indicated by the arrow in FIG. 1B and the c-axis direction of the lithium niobate film indicated by the arrow in FIG. 1C is 0.4° to 5°.

When the angle between the c-axis direction of the lithium niobate film forming the dielectric thin film 3 and the c-axis direction of the single crystal substrate 2 is within the above range, the crystallinity of the c-axis oriented in one in-plane direction is good (the half-width of the rocking curve is small), which is preferable in that an optical waveguide of an optical modulation element can be formed with a low driving voltage and low optical loss.

Here, the reason why the c-axis direction of the lithium niobate film grown by a vapor deposition method on the single crystal substrate 2 having a c-axis oriented in the in-plane direction is misaligned with the c-axis direction of the single crystal substrate 2 will be described with reference to the drawings by taking an example of the c-axis of the lithium niobate film grown by a vapor deposition method on a sapphire single crystal substrate having a c-axis oriented in the in-plane direction.

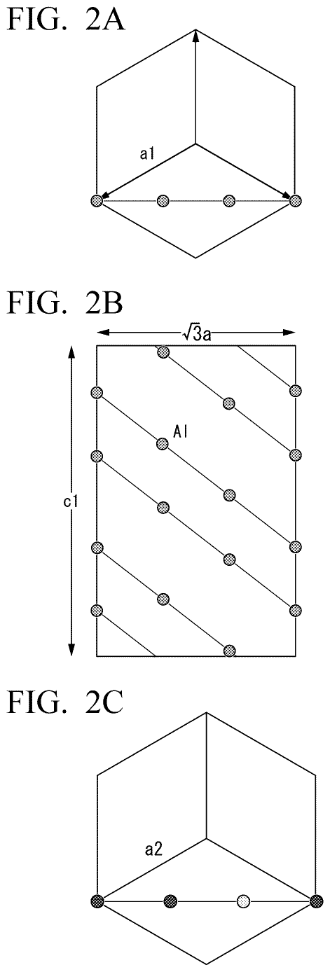

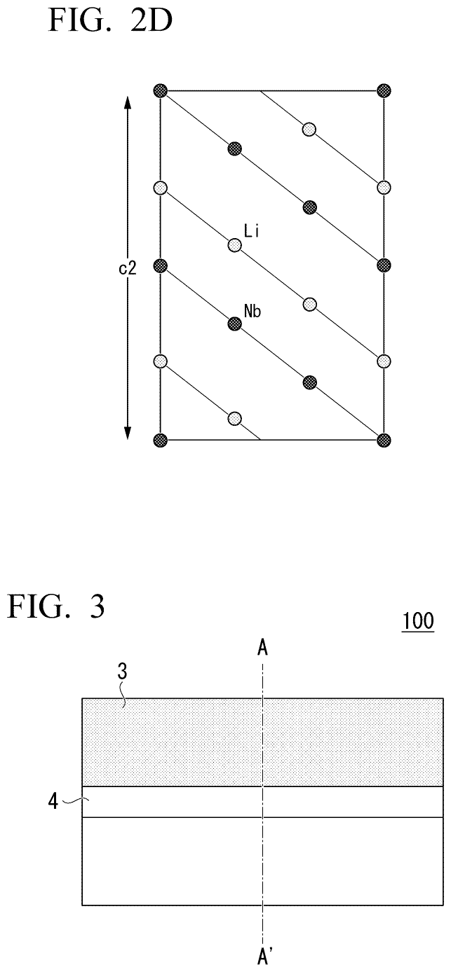

FIGS. 2A and 2B are diagrams for describing the arrangement of Al atoms in a sapphire single crystal substrate, where FIG. 2A is a schematic view showing the arrangement as viewed from the c-axis direction, and FIG. 2B is a schematic view showing the arrangement on the a-plane (1100). a1 shown in FIG. 2A and c1 shown in FIG. 2B are the lattice constants of a sapphire single crystal. As shown in FIGS. 2A and 2B, in the sapphire single crystal substrate, Al atoms are arranged on the a-plane at an angle to the c-axis direction (the up and down direction in FIG. 2B).

Further, FIGS. 2C and 2D are diagrams for describing the arrangement of Nb atoms and Li atoms in a lithium niobate film, where FIG. 2C is a schematic view showing the arrangement as viewed from the c-axis direction, and FIG. 2D is a schematic view showing the arrangement on the a-plane (1100). a2 shown in FIG. 2C and c2 shown in FIG. 2D are the lattice constants of lithium niobate crystal. As shown in FIGS. 2C and 2D, in the lithium niobate film, Li and Nb atoms are arranged obliquely on the a-plane in parallel to each other at an angle to the c-axis direction (the up and down direction in FIG. 2D).

The inclination of the arrangement of Al atoms relative to the c-axis of the sapphire single crystal substrate and the inclination θ of the arrangement of Nb atoms and Li atoms relative to the c-axis of the lithium niobate film can each be calculated by the following formula (1).

$$\begin{matrix}[ Math . 1 ] & \\ θ = \frac{π}{2} - {tan}^{- 1} \{ \frac{1}{2 \sqrt{3}} ( c / a ) \} & ( 1 )\end{matrix}$$

(In formula (1), a and c are the lattice constants of a sapphire single crystal or the lattice constants of a lithium niobate crystal.)

The lattice constant a1 of the sapphire single crystal substrate and the lattice constant a2 of the lithium niobate crystal are different values. Further, the lattice constant c1 of the sapphire single crystal substrate and the lattice constant c2 of the lithium niobate crystal are also different values. Therefore, in general, c1/a1 and c2/a2 are different. Therefore, the inclination of the arrangement of Al atoms relative to the c-axis of the sapphire single crystal substrate calculated by formula (1) does not match the inclination of the arrangement of Nb atoms and Li atoms relative to the c-axis of the lithium niobate film.

When a lithium niobate film (LiNbO₃ film) is epitaxially grown by a vapor deposition method on a sapphire single crystal substrate with its c-axis oriented in the in-plane direction, the Li atoms and Nb atoms, which are the raw materials for the lithium niobate film that reach the surface of the sapphire single crystal substrate, are arranged to be aligned due to the arrangement of Al atoms in the underlying sapphire single crystal substrate. However, as described above, the inclination of the arrangement of Al atoms relative to the c-axis of the sapphire single crystal substrate does not match the inclination of the arrangement of Nb atoms and Li atoms relative to the c-axis of the lithium niobate film. Therefore, when the Al atoms of the sapphire single crystal substrate and the Nb atoms and Li atoms of the lithium niobate film are arranged to be aligned, the c-axis direction of the lithium niobate film and the c-axis direction of the sapphire single crystal substrate are misaligned.

In the lithium niobate film grown by a vapor deposition method on the single crystal substrate 2 having a c-axis oriented in the in-plane direction, the angle between the c-axis direction of the single crystal substrate 2 and the c-axis direction of the lithium niobate film is determined by the difference in inclination between the atomic arrangement of the single crystal substrate and the arrangement of Nb atoms and Li atoms of the lithium niobate film, which is caused by the difference in lattice constants a and c between the single crystal substrate 2 and the lithium niobate crystal and by the conditions of the vapor deposition method used to grow the lithium niobate film.

In this embodiment, the lithium niobate film grown by a vapor deposition method on the single crystal substrate 2 having a c-axis oriented in the in-plane direction has a c-axis direction inclined by 0.4° to 5° with respect to the c-axis direction of the single crystal substrate 2. 0.4° occurs when the c2/a2 of the vapor-deposited lithium niobate film is equal to the c2/a2 of the bulk lithium niobate. The c2/a2 ratio of vapor-deposited lithium niobate films varies depending on the vapor deposition conditions. Generally, c2/a2 is smaller than the bulk value. Therefore, the inclination |θ₁−θ₂| between the c-axis of the sapphire substrate and the c-axis of lithium niobate becomes larger than 0.4°. On the other hand, if c2/a2 becomes too small, the amount of Li contained in the lithium niobate film may deviate significantly from the stoichiometric composition, or the lithium niobate film may become difficult to epitaxially grow. At the value corresponding to this lower limit of c2/a2, the inclination between the c-axis of the sapphire substrate and the c-axis of lithium niobate is 5°.

It is impossible to specify the difference between the dielectric thin film deposited substrate 1 of this embodiment having the lithium niobate film manufactured in this way and a bonded substrate manufactured, for example, by bonding a separately manufactured lithium niobate film onto the single crystal substrate 2 having a c-axis oriented in the in-plane direction such that the c-axis direction is inclined by 0.4° to 5° with respect to the c-axis direction of the single crystal substrate 2 by using wording that specifies the structure or characteristics of the object.

Further, there is no means for analyzing and specifying a lithium niobate film grown by a vapor deposition method on the single crystal substrate 2 having a c-axis oriented in the in-plane direction based on measurements, and thus in order to find means for analyzing and specifying the dielectric thin film deposited substrate 1 based on measurements, a significant amount of trial and error is required. Therefore, it is technically impossible or impractical to analyze and specify the structure or characteristics of the dielectric thin film deposited substrate 1 based on measurements.

When the lithium niobate film forming the dielectric thin film 3 is grown by a vapor deposition method, examples of the vapor deposition method include vacuum deposition, sputtering, and chemical vapor deposition (CVD). Among these, the lithium niobate film grown by sputtering is preferred. The reason is that it is the simplest method.

The fact that the c-axis of the lithium niobate film forming the dielectric thin film 3 is aligned in one in-plane direction of the single crystal substrate 2 can be confirmed, for example, by measuring the intensity of in-plane X-ray diffraction (φ scan) by an in-plane diffraction (in-plane diffraction) method using an X-ray diffraction device. Specifically, when the c-axis of the lithium niobate film is aligned in one in-plane direction of the single crystal substrate, two diffraction peaks are observed in the profile of the X-ray diffraction intensity relative to the φ axis, and the angle difference between the φ axes at which the two diffraction peaks are observed is 180°.

The fact that the lithium niobate film forming the dielectric thin film 3 is a single crystal film in which the c-axis is aligned in one in-plane direction of the single crystal substrate 2 can be confirmed, for example, by measuring the X-ray diffraction poles by the in-plane diffraction (in-plane diffraction) method using an X-ray diffraction device. Specifically, when the lithium niobate film is a single crystal film, the number and positions of the observed diffraction spots match the reference diffraction data.

Further, the angle between the c-axis direction of the single crystal substrate 2 and the c-axis direction of the lithium niobate film can be calculated using the results of measuring (φ scan) the in-plane X-ray diffraction intensity for each of the single crystal substrate 2 and the lithium niobate film by in-plane diffraction (in-plane diffraction), for example, using an X-ray diffraction device. Specifically, it can be calculated from the angle difference of the φ axis of observing the diffraction peak between the maximum value of the diffraction peak in the profile of X-ray diffraction intensity relative to the φ axis of the single crystal substrate 2 and the maximum value of the diffraction peak in the profile of X-ray diffraction intensity relative to the φ axis of the lithium niobate film.

### [Dielectric Thin Film Deposited Substrate Manufacturing Method]

Next, a method of manufacturing the dielectric thin film deposited substrate 1 of this embodiment will be described by an example. When manufacturing the dielectric thin film deposited substrate 1 of this embodiment, for example, the dielectric thin film 3 made of a lithium niobate film is formed on the main surface 2a of the single crystal substrate 2 using the method described below (dielectric thin film forming step).

### (Dielectric Thin Film Forming Step)

In the dielectric thin film forming step, a lithium niobate film having a c-axis oriented in one in-plane direction of the single crystal substrate 2 is epitaxially grown by a vapor deposition method on the main surface 2a of the single crystal substrate 2 having a c-axis aligned in the in-plane direction. Examples of vapor deposition methods for growing the dielectric thin film 3 include vacuum deposition, sputtering, and chemical vapor deposition (CVD).

Among these, it is preferable to use sputtering as the vapor deposition method for growing the dielectric thin film 3.

When sputtering is used as a method of depositing the dielectric thin film 3, a target having a composition in the range of Li/(Li+Nb)=48 mass % to 51 mass %, for example, can be used.

The shape of the target used to form the dielectric thin film 3 is not particularly limited. The target is preferably a circular target having a planar area twice or more the single crystal substrate 2 in order to obtain the dielectric thin film 3 having a uniform thickness. Further, the dielectric thin film 3 is preferably formed by arranging a circular target coaxially with the circular single crystal substrate 2 in order to obtain the dielectric thin film 3 having a uniform thickness.

When sputtering is used as a method of depositing the dielectric thin film 3, for example, a method can be used in which the distance between the target and the single crystal substrate 2 is set to 100 mm to 200 mm, a mixed gas of Ar and O₂ is used as a sputtering gas, the O₂ ratio in the sputtering gas is set to 35% to 60%, the gas pressure is set to 0.05 Pa to 0.15 Pa, pre-sputtering is performed for 100 seconds to 300 seconds, the temperature of the single crystal substrate 2 is set to 450° C. to 700° C., and a power of 1500 W to 2000 W is applied to deposit a film until a predetermined thickness is achieved.

Accordingly, the dielectric thin film 3 is obtained which is made of a lithium niobate film having a c-axis aligned in one in-plane direction of the single crystal substrate 2, and the angle formed between the c-axis direction of the single crystal substrate 2 and the c-axis direction of the lithium niobate film is 0.4° to 5°.

It is preferable that the dielectric thin film 3 be formed in a so-called single step without changing the film forming conditions midway.

Through the above steps, the dielectric thin film deposited substrate 1 of this embodiment is obtained.

The dielectric thin film deposited substrate 1 of this embodiment has the single crystal substrate 2 having a c-axis oriented in the in-plane direction and the dielectric thin film 3 formed on the single crystal substrate 2, and the dielectric thin film 3 is made of a lithium niobate film having a c-axis aligned in one in-plane direction. Therefore, the optical waveguide element having an optical waveguide made of the dielectric thin film 3 of the dielectric thin film deposited substrate 1 of this embodiment is a so-called x-cut optical waveguide element. Therefore, for example, by forming an optical waveguide that allows TE mode light to be incident using the dielectric thin film deposited substrate 1 of this embodiment, it is possible to form an optical waveguide of an optical modulation element which has a low driving voltage and low optical loss and in which the polarization direction of the light incident to the optical waveguide matches the c-axis of the lithium niobate film.

### [Optical Waveguide Element]

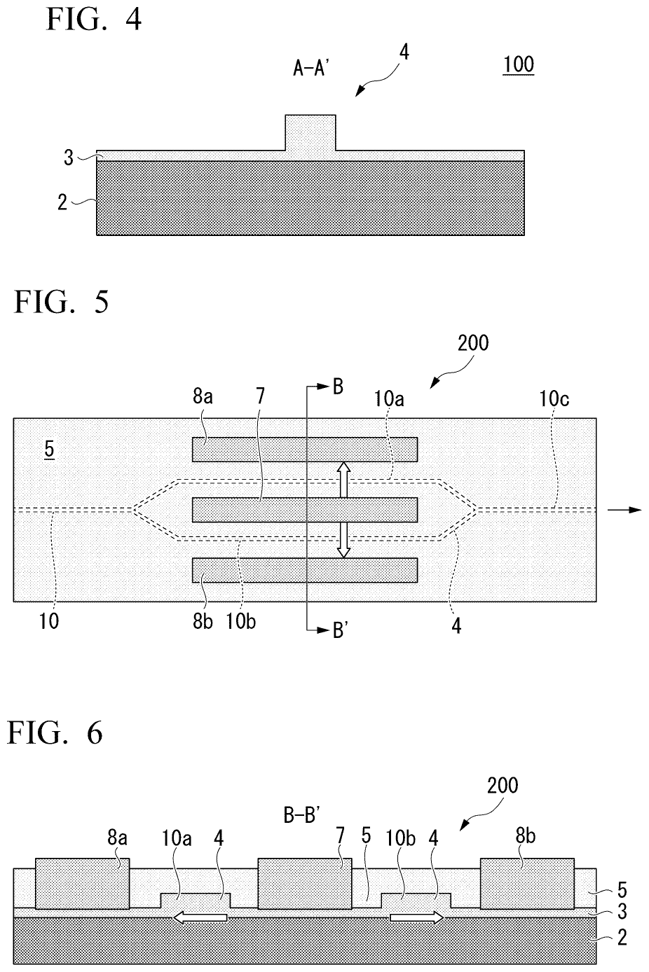

FIG. 3 is a plan view showing an example of an optical waveguide element 100 provided with the dielectric thin film deposited substrate 1 shown in FIGS. 1A to 1C. FIG. 4 is a cross-sectional view of the optical waveguide element 100 shown in FIG. 3 taken along line A-A′.

In the optical waveguide element 100 shown in FIGS. 3 and 4, the same reference numerals are used to designate the members of the dielectric thin film deposited substrate 1 shown in FIGS. 1A to 1C, and the description thereof will be omitted.

The optical waveguide element 100 shown in FIGS. 3 and 4 has an optical waveguide formed of a ridge portion 4 obtained by processing the dielectric thin film 3 in the dielectric thin film deposited substrate 1 shown in FIGS. 1A to 1C into a ridge shape (convex shape). The ridge portion 4 of the optical waveguide element 100 is a portion through which the TE mode light propagates.

The optical waveguide element 100 shown in FIGS. 3 and 4 can be manufactured by processing the dielectric thin film 3 of the dielectric thin film deposited substrate 1 shown in FIGS. 1A to 1C into a ridge shape (convex shape). The dielectric thin film 3 can be processed into a ridge shape by a known method such as etching.

The optical waveguide element 100 shown in FIGS. 3 and 4 has an optical waveguide made of the dielectric thin film 3 of the dielectric thin film deposited substrate 1 shown in FIGS. 1A to 1C. Therefore, the optical waveguide of the optical waveguide element 100 of this embodiment is made of a lithium niobate film having a c-axis aligned in one in-plane direction of the single crystal substrate 2, and is an x-cut optical waveguide element in which light propagates in TE mode. Therefore, the optical waveguide element 100 of this embodiment can be suitably used as an optical waveguide of an optical modulation element having low optical loss and having the polarization direction of the light incident on the optical waveguide matching the c-axis of the lithium niobate film, for example, when TE mode light is incident on the optical waveguide.

Further, in the optical waveguide element 100 of this embodiment, the c-axis direction of the lithium niobate film forming the optical waveguide matches the polarization direction of the TE mode light. Therefore, the optical waveguide of the optical waveguide element 100 of this embodiment can be coupled to an output port of a laser light source, so that TE mode light emitted from the laser light source is directly incident thereon. Therefore, in the optical waveguide element 100 of this embodiment, as in the case of, for example, a z-cut optical waveguide element made of a lithium niobate film in which the c-axis is aligned in the thickness direction, there is no need to convert TE mode light to TM mode light using an optical conversion device before light is incident on the optical waveguide, and no optical loss occurs due to the conversion of the polarization direction of light.

### [Optical Modulation Element]

FIG. 5 is a plan view showing an example of a Mach-Zehnder type optical modulation element 200 provided with the dielectric thin film deposited substrate 1 shown in FIGS. 1A to 1C. FIG. 6 is a cross-sectional view of the light modulation element 200 shown in FIG. 5 taken along the line B-B′.

In the optical modulation element 200 shown in FIGS. 5 and 6, the same reference numerals are used to designate the members of the dielectric thin film deposited substrate 1 shown in FIGS. 1A to 1C, and the description thereof will be omitted.

The optical modulation element 200 shown in FIGS. 5 and 6 is a device that applies a voltage to a Mach-Zehnder interferometer formed by an optical waveguide 10 to modulate light propagating within the optical waveguide 10. As shown in FIG. 5, the optical waveguide 10 has a first optical waveguide 10a and a second optical waveguide 10b branched from a single input optical waveguide, and an output optical waveguide 10c in which the first optical waveguide 10a and the second optical waveguide 10b are coupled.

The optical modulation element 200 shown in FIGS. 5 and 6 has the ridge portion 4 formed by processing the dielectric thin film 3 of the dielectric thin film deposited substrate 1 shown in FIGS. 1A to 1C into a ridge shape (convex shape). In the optical modulation element 200, the optical waveguide 10 is formed by the ridge portion 4.

As shown in FIGS. 5 and 6, two strip-shaped second electrodes 8a and 8b and one strip-shaped first electrode 7 are arranged substantially parallel to each other on the slab portion made of the dielectric thin film 3. The slab portion made of the dielectric thin film 3 is obtained by thinning a part of the upper surface of the dielectric thin film 3 in the dielectric thin film deposited substrate 1 shown in FIGS. 1A to 1C by etching or the like.

As shown in FIGS. 5 and 6, the second electrode 8a and the first electrode 7 are arranged opposite to each other and spaced apart in the in-plane direction of the single crystal substrate 2, and the first optical waveguide 10a is disposed between the second electrode 8a and the first electrode 7. Further, the second electrode 8b and the first electrode 7 are arranged opposite to each other and spaced apart in the in-plane direction of the single crystal substrate 2, and the second optical waveguide 10b is disposed between the second electrode 8b and the first electrode 7. In this embodiment, the distances between the second and first electrode 8a and 7 and the first optical waveguide 10a, and the distances between the second and first electrodes 8b and 7 and the second optical waveguide 10b are all approximately the same.

The first electrode 7 and the second electrodes 8a and 8b may be made of a known conductive film, such as a single-layer conductive film made of an Au film, a Cu film, an Al film, or an ITO (indium tin oxide) film, or a laminated film made of a Ti film and an Au film. The first electrode 7 and the second electrodes 8a and 8b may be made of the same material, or may be made of different materials.

In this embodiment, the first electrode 7 functions as a signal electrode. Further, the second electrodes 8a and 8b are reference electrodes at a reference potential. The first electrode 7 and the second electrode 8a apply a predetermined voltage to the dielectric thin film 3 in the in-plane direction to change the refractive index of the first optical waveguide 10a. The first electrode 7 and the second electrode 8b apply a predetermined voltage to the dielectric thin film 3 in the in-plane direction to change the refractive index of the second optical waveguide 10b.

It is preferable that the first optical waveguide 10a disposed between the first electrode 7 and the second electrode 8a and the second optical waveguide 10b disposed between the first electrode 7 and the second electrode 8b extend in a direction approximately perpendicular to the c-axis direction of the dielectric thin film 3 (the up and down direction in FIG. 5 and the left and right direction in FIG. 6). In this case, as shown in FIGS. 5 and 6, the phase change amount of the light propagating through the first optical waveguide 10a and the second optical waveguide 10b with respect to the applied voltage is maximized by aligning the extension directions of the first electrode 7 and the second electrodes 8a and 8b in a direction substantially perpendicular to the c-axis direction of the dielectric thin film 3. Therefore, the operating voltage of the Mach-Zehnder interferometer included in the optical modulation element 200 can be reduced.

As shown in FIGS. 5 and 6, a buffer layer 5 is formed on the ridge portion 4 forming the optical waveguide 10. As shown in FIG. 6, the buffer layer 5 is formed to cover the upper and side surfaces of the ridge portion 4 forming the second optical waveguide 10b and the first optical waveguide 10a. Further, the buffer layer 5 is embedded between the first electrode 7 and the second electrodes 8a and 8b by exposing the upper surfaces of the first electrode 7 and the second electrodes 8a and 8b. The buffer layer 5 may be made of, for example, a SiO₂ film or a thin film of SiO₂ doped with an oxide of a metal element.

### [Optical Modulation Element Manufacturing Method]

The light modulation element 200 shown in FIGS. 5 and 6 can be manufactured, for example, by the manufacturing method described below.

First, the dielectric thin film 3 in the dielectric thin film deposited substrate 1 shown in FIGS. 1A to 1C is processed into a ridge shape (convex shape) using a known method such as etching to form the optical waveguide 10 consisting of the ridge portion 4, and also to form a slab portion consisting of the dielectric thin film 3.

Next, the second electrodes 8a and 8b and first electrode 7 are formed in contact with the upper surface of the slab portion made of the dielectric thin film 3 using a known method such as sputtering, vacuum deposition, or plating.

Thereafter, the buffer layer 5 is formed to cover the upper and side surfaces of the ridge portion 4 and to fill the gap between the first electrode 7 and the second electrodes 8a and 8b using a known method such as sputtering, vacuum deposition, pulsed laser ablation (PLD), or chemical vapor deposition (CVD).

Through the above steps, the optical modulation element 200 shown in FIGS. 5 and 6 is obtained.

The optical modulation element 200 of this embodiment includes the dielectric thin film deposited substrate 1 shown in FIGS. 1A to 1C. Therefore, the optical waveguide 10 of the optical modulation element 200 of this embodiment is made of a lithium niobate film having a c-axis aligned in one in-plane direction of the single crystal substrate 2. Therefore, in the optical modulation element 200 of this embodiment, when TE mode light is incident on the optical waveguide, the polarization direction of the light incident on the optical waveguide matches the c-axis of the lithium niobate film, and the driving voltage is low and optical loss is low.

Further, since the optical modulation element 200 of this embodiment has the optical waveguide 10 made of a lithium niobate film having a c-axis aligned in one in-plane direction of the single crystal substrate 2, the first optical waveguide 10a and the second optical waveguide 10b can be disposed between the first electrode 7 and the second electrode 8a, and between the first electrode 7 and the second electrode 8b, which are arranged opposite each other and spaced apart in the in-plane direction on the dielectric thin film 3 made of the lithium niobate film, respectively. Therefore, the optical modulation element 200 of this embodiment has a different design compared to, for example, an element having an optical waveguide made of a lithium niobate film having a c-axis in the thickness direction.

Further, in the optical modulation element 200 of this embodiment, the c-axis direction of the lithium niobate film forming the optical waveguide matches the polarization direction of the TE mode light. Therefore, for example, there is no need to convert TE mode light into TM mode light using an optical conversion device before allowing the light to be incident on the optical waveguide, there is no optical loss associated with converting the polarization direction of the light, and there is no need to secure space for installing the optical conversion device.

Therefore, the optical modulation element 200 of this embodiment can be suitably used as, for example, an optical communication device.

Although the preferred embodiments of the present disclosure have been described above, the present disclosure is not limited to the above-described embodiments. Of course, the present disclosure can be modified in various ways without departing from the spirit of the present disclosure, and such modifications are also included within the scope of the present disclosure.

### EXAMPLES

### Example 1

The dielectric thin film deposited substrate 1 shown in FIGS. 1A to 1C was produced by the method described below.

As the single crystal substrate 2, a 4-inch sapphire single crystal substrate having a c-axis oriented in the in-plane direction (the main surface 2a is the a-plane) was prepared.

### (Dielectric Thin Film Forming Step)

In the dielectric thin film forming step, the dielectric thin film 3 was formed on the main surface 2a of the single crystal substrate 2 by epitaxial growth using a sputtering method.

As the target, one having a circular shape with a diameter of 8 inches and a composition of Li/(Li+Nb)=50 atomic % was used.

The dielectric thin film 3 was formed by arranging the target coaxially with the single crystal substrate 2 so that the distance from the main surface 2a of the single crystal substrate 2 was 180 mm.

Further, the dielectric thin film 3 was formed by using a mixed gas of Ar and O₂ as a sputtering gas, setting the O₂ ratio in the sputtering gas to 40%, setting the gas pressure to 0.09 Pa, performing pre-sputtering for 180 seconds, setting the temperature of the single crystal substrate 2 to 600° C., and applying a power of 1800 W to form the film. The dielectric thin film 3 was formed in a so-called single step without changing the film forming conditions during the process.

Through the above steps, the dielectric thin film deposited substrate 1 of Example 1 was obtained.

For the dielectric thin film deposited substrate 1 of Example 1 obtained in this way, the sapphire single crystal substrate forming the single crystal substrate 2 and the lithium niobate film forming the dielectric thin film 3 were evaluated using a fully automatic multipurpose X-ray diffractometer (manufactured by Rigaku Corporation, SmartLab (rotating anticathode type)) by the methods shown below (Evaluation 1) to (Evaluation 3).

The light source for irradiating X-rays was CuKα rays (wavelength=1.54186 Å). The output of the light source was 45 kV×200 mA.

Further, as reference diffraction data, JCPDS (ASTM) Card No. 20-0631 was referenced for lithium niobate (LiNbO₃) single crystal, and JCPDS (ASTM) Card No. 10-0173 was referenced for sapphire single crystal.

### (Evaluation 1)

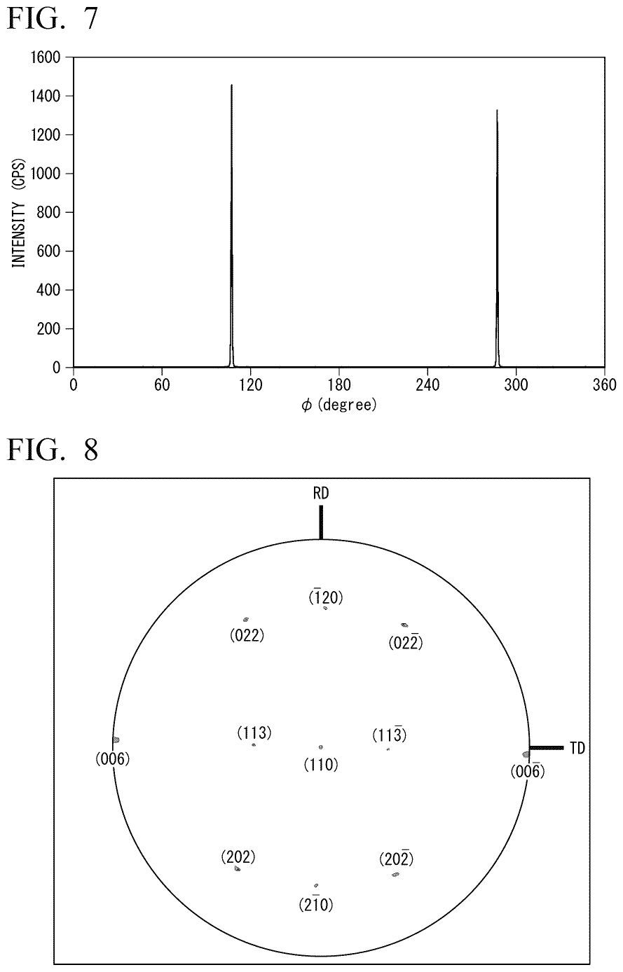

The lithium niobate film provided on the dielectric thin film deposited substrate 1 of Example 1 was subjected to measurement (scanning) of the X-ray diffraction intensity relative to the φ axis by the in-plane diffraction method. The X-ray diffraction intensity was measured by fixing the installation angle of the monochromator as a detector at 2θχ=38.94° so that the diffraction plane (006) perpendicular to the c-axis direction of LiNbO₃ could be observed. Further, the X-ray diffraction intensity was measured by placing the dielectric thin film deposited substrate 1 on a horizontal rotation stage and changing the stage rotation angle φ in the range of 0° to 360° while irradiating the substrate with X-rays. The results are shown in FIG. 7.

FIG. 7 is a profile of X-ray diffraction intensity obtained by the measurement (φ scan) of an in-plane X-ray diffraction intensity of a lithium niobate film forming a dielectric thin film 3 of a dielectric thin film deposited substrate of Example 1. As shown in FIG. 7, only two diffraction peaks originating from the diffraction plane (006) were observed in the X-ray diffraction intensity profile. Further, as shown in FIG. 7, the angle difference between the φ axes at which the two diffraction peaks were observed was 180°. From these results, it was confirmed that the c-axis of LiNbO₃ provided on the dielectric thin film deposited substrate 1 in Example 1 was aligned in one in-plane direction of the single crystal substrate 2.

### (Evaluation 2)

The lithium niobate film provided on the dielectric thin film deposited substrate 1 of Example 1 was subjected to X-ray diffraction pole measurement by the in-plane diffraction method. The installation angle of the monochromator as a detector was set to 2θχ=38.94°, and the slit configuration was adjusted so that diffracted light with a grating spacing d in the range of 2.1 to 2.6 Å could be observed. Then, the dielectric thin film deposited substrate 1 was placed on a horizontal rotation stage, and the diffracted X-rays at the poles were measured while irradiating the substrate with X-rays. The results are shown in FIG. 8.

FIG. 8 is a diagram showing the results of measuring the X-ray diffraction poles of the lithium niobate film forming the dielectric thin film 3 of the dielectric thin film deposited substrate in Example 1. As shown in FIG. 8, eleven diffraction spots were observed. The positions of the eleven observed diffraction spots matched the respective spots (006), (00-6), (110), (113), (11-3), (202), (20-2), (022), (02-2), (2-10), and (−120) in the reference diffraction data for the LiNbO₃ single crystal when the measured diffraction plane was the a-plane. Accordingly, it was confirmed that the dielectric thin film 3 of the dielectric thin film deposited substrate 1 of Example 1 was a LiNbO₃ single crystal film.

### (Evaluation 3)

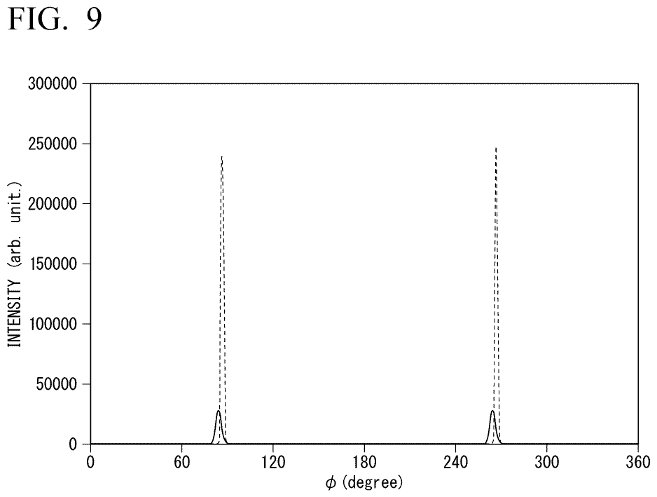

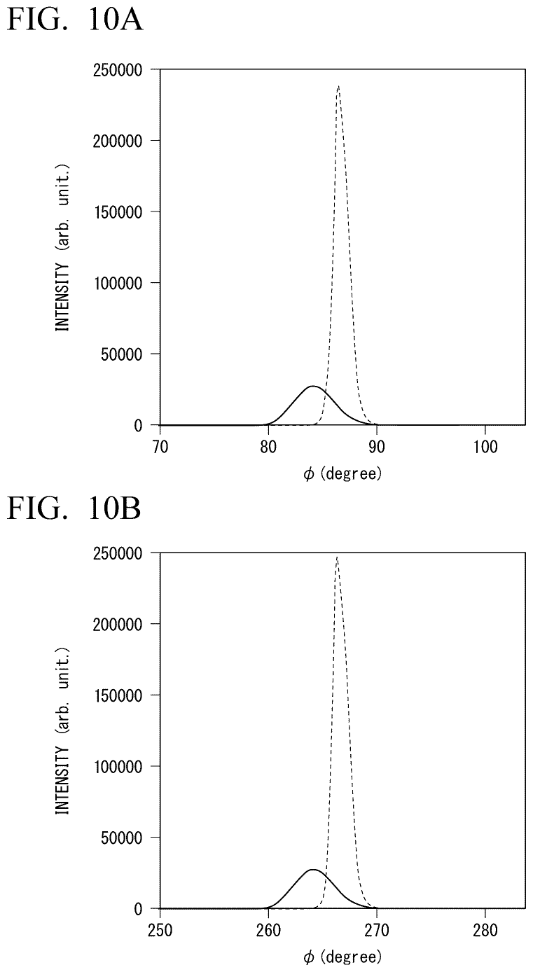

The sapphire single crystal substrate of the dielectric thin film deposited substrate 1 of Example 1 was measured (scanned) for the intensity of X-ray diffraction relative to the φ axis by the in-plane diffraction method. The X-ray diffraction intensity was measured by fixing the installation angle of the monochromator as a detector at 2θχ=41.68° so that the diffraction plane (006) perpendicular to the c-axis direction of the sapphire single crystal could be observed. Further, the X-ray diffraction intensity was measured without moving the relative position of the dielectric thin film deposited substrate 1 from the state in which the X-ray diffraction intensity relative to the φ axis of the lithium niobate film was measured in (Evaluation 1). Accordingly, the relative position with respect to the c-axis direction of LiNbO₃ could be checked. Then, in the same way as in (Evaluation 1), the stage rotation angle φ was changed in the range of 0° to 360° while irradiating the substrate with X-rays, and the X-ray diffraction intensity was measured. The results are shown in FIGS. 9, 10A, and 10B.

FIG. 9 shows an X-ray diffraction intensity profile obtained by measuring (φ scan) the in-plane X-ray diffraction intensity of the sapphire single crystal substrate forming the single crystal substrate 2 of the dielectric thin film deposited substrate of Example 1. FIG. 9 shows the X-ray diffraction intensity profile of the sapphire single crystal substrate, as well as the X-ray diffraction intensity profile of the lithium niobate film forming the dielectric thin film 3 shown in FIG. 7, measured in (Evaluation 1). Further, FIG. 10A is an enlarged view of a part of FIG. 9 showing the X-ray diffraction intensity profile, which is a profile around an angle of 85° on the φ axis. FIG. 10B is an enlarged view of a part of FIG. 9 showing the X-ray diffraction intensity profile, which is a profile around an angle of 265° on the φ axis. In FIGS. 9, 10A, and 10B, the dotted lines show the results for the sapphire single crystal substrate, and the solid lines show the results for the lithium niobate film.

As shown in FIG. 9, only two diffraction peaks originating from the diffraction plane (006) were observed in the X-ray diffraction intensity profile. Further, as shown in FIG. 9, the angle difference between the φ axes at which the two diffraction peaks were observed was 180°. From these results, it can be seen that the sapphire single crystal substrate on which the dielectric thin film deposited substrate 1 of Example 1 is formed has a c-axis aligned in one in-plane direction of the single crystal substrate 2. Therefore, it was confirmed that the crystal orientation of the main surface 2a was the a-plane.

Further, as shown in FIG. 9, the profile of the sapphire single crystal substrate indicated by the dotted line does not match the angle of the peak position of the lithium niobate film indicated by the solid line. From this, it was confirmed that the c-axis direction of the sapphire single crystal substrate and the c-axis direction of the lithium niobate film were misaligned.

Further, as shown in FIGS. 10A and 10B, the two diffraction peaks (maximum values) in the profile of the X-ray diffraction intensity relative to the φ axis of the sapphire single crystal substrate were at 86.5° and 266.5°. Further, as shown in FIGS. 10A and 10B, the two diffraction peaks (maximum values) in the X-ray diffraction intensity profile relative to the φ axis of the lithium niobate film were 84.2° and 264.2°. Then, the angular difference between the φ axes at which the diffraction peaks of the sapphire single crystal substrate and the lithium niobate film were observed (86.5−84.2=266.5−264.2=2.3) was 2.3°. Accordingly, it was confirmed that in the dielectric thin film deposited substrate 1 of Example 1, the angle formed between the c-axis direction of the single crystal substrate 2 and the c-axis direction of the lithium niobate film was 2.3°.

### EXPLANATION OF REFERENCES

1: Dielectric thin film deposited substrate
2: Single crystal substrate
2a: Main surface
3: Dielectric thin film
4: Ridge portion
5: Buffer layer
7: First electrode
8a, 8b: Second electrode
10: Optical waveguide
10a: First optical waveguide
10b: Second optical waveguide
10c: Output optical waveguide
100: Optical waveguide element
200: Optical modulation element.

What is claimed is:

1. A dielectric thin film deposited substrate comprising:
a single crystal substrate having a c-axis oriented in an in-plane direction; and
a dielectric thin film formed on and in contact with the single crystal substrate,
wherein the dielectric thin film is made of a lithium niobate film having a c-axis aligned in one in-plane direction.

2. The dielectric thin film deposited substrate according to claim 1,
wherein an angle formed between the c-axis direction of the single crystal substrate and the c-axis direction of the lithium niobate film is 0.4° to 5°.

3. The dielectric thin film deposited substrate according to claim 1,
wherein the single crystal substrate is a sapphire single crystal substrate.

4. The dielectric thin film deposited substrate according to claim 1,
wherein the lithium niobate film is grown by a vapor deposition method.

5. The dielectric thin film deposited substrate according to claim 1,
wherein the lithium niobate film is grown by sputtering.

6. The dielectric thin film deposited substrate according to claim 1,
wherein the lithium niobate film has a composition represented by a general formula of LiₓNbA_{y}O_{z}, and
wherein in the general formula, A is an element other than Li, Nb, and O, x is 0.5 to 1.2, y is 0 to 0.5, and z is 1.5 to 4.

7. The dielectric thin film deposited substrate according to claim 6,
wherein in the general formula, A represents one or more elements selected from K, Na, Rb, Cs, Be, Mg, Ca, Sr, Ba, Ti, Zr, Hf, V, Cr, Mo, W, Fe, Co, Ni, Zn, Sc, Ce, and Ta, and
wherein in the general formula, x is 0.9 to 1.05, and z is 2.5 to 3.5.

8. The dielectric thin film deposited substrate according to claim 7,
wherein the lithium niobate film is mainly consisting of lithium niobate (LiNbO₃).

9. The dielectric thin film deposited substrate according to claim 8,
wherein the lithium niobate film is a single phase film consisting of LiNbO₃.

10. The dielectric thin film deposited substrate according to claim 1,
wherein the dielectric thin film has a film thickness of 0.5 μm to 2 μm.

11. An optical waveguide element comprising:
the dielectric thin film deposited substrate according to claim 1; and
an optical waveguide made of the dielectric thin film.

12. An optical modulation element comprising:
the dielectric thin film deposited substrate according to claim 1;
an optical waveguide made of the dielectric thin film; and
a first electrode and a second electrode provided on the dielectric thin film and arranged opposite to each other and spaced apart in the in-plane direction,
wherein the optical waveguide is disposed between the first electrode and the second electrode.

13. A method of manufacturing the dielectric thin film deposited substrate according to claim 1, comprising:
a dielectric thin film forming step of growing, by a vapor deposition method, a lithium niobate film having a c-axis oriented in one in-plane direction on a single crystal substrate having a c-axis aligned in the in-plane direction.

14. The dielectric thin film deposited substrate manufacturing method according to claim 13,
wherein the vapor deposition method is sputtering.

15. The dielectric thin film deposited substrate manufacturing method according to claim 13,
wherein a ratio of an Li content to a total content of Li and Nb in a target used in the sputtering, Li/(Li+Nb), is within a range of 48 mass % to 51 mass %.

16. The dielectric thin film deposited substrate manufacturing method according to claim 15,
wherein the single crystal substrate and the target have a disc shape, the target has a planar area at least twice that of the single crystal, and the single crystal substrate and the target are arranged coaxially.

17. The dielectric thin film deposited substrate manufacturing method according to claim 16,
wherein in the sputtering, a distance between the target and the single crystal substrate is set to 100 mm to 200 mm, a mixed gas of Ar and O₂ is used as a sputtering gas, an O₂ ratio in the sputtering gas is set to 35% to 60%, a gas pressure is set to 0.05 Pa to 0.15 Pa, pre-sputtering is performed for 100 seconds to 300 seconds, the temperature of the single crystal substrate is set to 450° C. to 700° C., and a power of 1500 W to 2000 W is applied to form a dielectric thin film until a predetermined thickness is achieved.

18. An optical modulation element manufacturing method comprising:
processing the dielectric thin film of the dielectric thin film deposited substrate according to claim 1 into a ridge shape to form an optical waveguide consisting of a ridge portion and a slab portion consisting of the dielectric thin film,
forming a plurality of second electrodes in contact with an upper surface of the slab portion and a first electrode provided between the plurality of second electrodes; and
forming a buffer layer to cover upper and side surfaces of the ridge portion and to fill a gap between the first electrode and the second electrodes.
